(19) United States
(12) Patent Application Publication
(10) Pub. No.: US 2025/0268014 A1
(43) Pub. Date: Aug. 21, 2025

(54) DISPLAY DEVICE

(71) Applicant: Samsung Display Co., LTD., Yongin-si (KR)

(72) Inventor: Yoon-Ho KANG, Yongin-si (KR)

(21) Appl. No.: 18/982,964

(22) Filed: Dec. 16, 2024

(30) Foreign Application Priority Data
Feb. 15, 2024 (KR) 10-2024-0022015

(51) Int. Cl. H10K 50/115; H10K 50/15; H10K 50/16; H10K 50/165; H10K 59/38

(52) U.S. Cl. CPC H10K 50/115; H10K 50/156; H10K 50/165; H10K 50/166; H10K 59/38

(57) ABSTRACT

A display device includes a substrate including a red light emitting region, a green light emitting region, and a blue light emitting region, a transistor on the substrate, a first light emitting element electrically connected to the transistor and overlapping the blue light emitting region, and a capping layer above the first light emitting element. The first light emitting element includes a first electrode, a first light emitting layer on the first electrode, a first electron transport layer on the first light emitting layer, and a second electrode on the first electron transport layer, where a first passivation layer is between the second electrode and the capping layer, between the second electrode and the first electron transport layer, or on an upper surface of the capping layer, and is spaced apart from the red light emitting region and the green light emitting region.

### CROSS-REFERENCE TO RELATED APPLICATION

The present application claims priority to and the benefit of Korean Patent Application No. 10-2024-0022015, filed on Feb. 15, 2024, in the Korean Intellectual Property Office, the entire content of which is incorporated herein by reference.

### BACKGROUND

### 1. Field

Embodiments of this disclosure relates to a display device.

### 2. Description of the Related Art

In a light emitting element, holes supplied from an anode and electrons supplied from a cathode combine within a light emitting layer formed between the anode and the cathode to form an exciton. As this exciton stabilizes, the light emitting element emits light.

Light emitting elements have various features, such as a wide viewing angle, a fast response speed, a thinness, and a low power consumption, so they are widely applied to various suitable electrical devices and electronic devices, such as televisions, monitors, and mobile phones.

### SUMMARY

One or more aspects of embodiments of the present disclosure are directed toward a display device having an improved lifespan and reliability of a light emitting element.

Additional aspects of embodiments will be set forth in part in the description which follows and, in part, will be apparent from the description, or may be learned by practice of the presented embodiments.

In one or more embodiments, a display device may include a substrate including a red light emitting region, a green light emitting region, and a blue light emitting region, a transistor on the substrate, a first light emitting element electrically connected to the transistor and overlapping the blue light emitting region, and a capping layer above the first light emitting element, where the first light emitting element may include a first electrode, a first light emitting layer on the first electrode, a first electron transport layer on the first light emitting layer, and a second electrode on the first electron transport layer, and where a first passivation layer may be between the second electrode and the capping layer, between the second electrode and the first electron transport layer, and/or on one of top surfaces (e.g., an upper surface) of the capping layer. The first passivation layer may be spaced apart from (separated from) the red light emitting region and the green light emitting region.

In one or more embodiments, the first passivation layer may be between the second electrode and the capping layer.

In one or more embodiments, the display device may further include a blue color filter between the first passivation layer and the capping layer.

In one or more embodiments, the first passivation layer may be between the first electron transport layer and the second electrode.

In one or more embodiments, the display device may further include a blue color filter between the first passivation layer and the second electrode.

In one or more embodiments, the display device may further include a second light emitting element overlapping the red light emitting region, and a third light emitting element overlapping the green light emitting region.

In one or more embodiments, the second light emitting element may include a second light emitting layer including a first quantum dot, a second electron transport layer on the second light emitting layer, and a second electrode on the second electron transport layer.

In one or more embodiments, the second electron transport layer may include ZnMgO.

In one or more embodiments, the third light emitting element may include a third light emitting layer including a second quantum dot, a third electron transport layer on the third light emitting layer, and a second electrode on the third electron transport layer.

In one or more embodiments, the third electron transport layer may include ZnMgO.

In one or more embodiments, the first passivation layer may include at least one of silicon nitride, silicon oxide, and/or silicon oxynitride.

In one or more embodiments, the first light emitting layer may include an organic material.

In one or more embodiments, the second electron transport layer and the third electron transport layer may include the same material.

In one or more embodiments, the first electron transport layer may include a different material from the second electron transport layer.

In one or more embodiments, the first electron transport layer, the second electron transport layer, and the third electron transport layer may be spaced apart from (separated from) each other with a partition wall therebetween.

In one or more embodiments, the first light emitting element may include a first hole injection layer and a first hole transport layer, the second light emitting element may include a second hole injection layer and a second hole transport layer, and the third light emitting element may include a third hole injection layer and a third hole transport layer, where the first hole injection layer, the second hole injection layer, and the third hole injection layer may be spaced apart from (separated from) each other, and the first hole transport layer, the second hole transport layer, and the third hole transport layer may be spaced apart from (separated from) each other.

In one or more embodiments, a display device may include a substrate including a red light emitting region, a green light emitting region, and a blue light emitting region, a plurality of transistors on the substrate, a first light emitting element, a second light emitting element, and a third light emitting element each electrically connected to the plurality of transistors and emitting light of different colors, a capping layer on the first light emitting element, the second light emitting element, and the third light emitting element, and a first passivation layer between the first light emitting layer and the capping layer, where the first light emitting element may include a first electrode, a first light emitting layer on the first electrode, a first electron transport layer on the first light emitting layer, and a second electrode on the first electron transport layer, where the second light emitting element may include a second light emitting layer, the third light emitting element may include a third light emitting layer, and the first passivation layer may be separated from (separated from) the second light emitting layer and the third light emitting layer along a thickness direction of the substrate.

In one or more embodiments, the display device may further include a partition wall between the first light emitting layer, the second light emitting layer, and the third light emitting layer, and the second electrode and the capping layer may be provided continuously throughout light emitting layers (e.g., the first light emitting layer, the second light emitting layer, and the third light emitting layer).

In one or more embodiments, the second light emitting element may further include a second electron transport layer on the second light emitting layer, and the third light emitting element may further include a third electron transport layer on the third light emitting layer, the first electron transport layer, the second electron transport layer, and the third electron transport layer may be spaced apart from (separated from) each other with an upper partition wall therebetween, the second electron transport layer and the third electron transport layer may include the same material, and the second electron transport layer and the first electron transport layer may include different materials.

In one or more embodiments, the display device may further include a blue color filter in contact with the first passivation layer.

In one or more embodiments, the blue color filter may be on the second electrode, the first passivation layer may be on the blue color filter, and the capping layer may be on the first passivation layer.

According to one or more embodiments of the present disclosure, a damage to the third light emitting layer in the blue light emitting region may be prevented (or reduced), and defects in the electron transport layer in the red light emitting region and the green light emitting region may be improved, thereby increasing the reliability of the display device.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIG. 1 is a cross-sectional view of a display device according to one or more embodiments of the present disclosure.

FIG. 2 is a flowchart of a method of manufacturing some components of a display device according to one or more embodiments of the present disclosure.

FIG. 3 is a diagram schematically showing a chamber for manufacturing a display device according to one or more embodiments of the present disclosure.

FIG. 4 and FIG. 5 are cross-sectional views of a display device according to another embodiment of the present disclosure.

FIG. 6 is a cross-sectional view of a display device according to another embodiment of the present disclosure.

FIG. 7 is a flowchart of a method of manufacturing some components of the display device according to the embodiment of FIG. 6.

FIG. 8 and FIG. 9 are cross-sectional views of a display device according to yet another embodiment of the present disclosure.

### DETAILED DESCRIPTION

Hereinafter, with reference to the attached drawings, one or more embodiments of the present disclosure will be described in more detail so that those skilled in the art may easily implement the subject matter of the present disclosure.

The subject matter of the disclosure may be implemented in many different forms and is not limited to the embodiments described herein.

In order to clearly explain the subject matter of the present disclosure, parts that are not relevant to the description may not be provided, and identical or similar components are assigned the same reference numerals throughout the specification.

In addition, the size and thickness of each component shown in the drawings may be arbitrarily shown for convenience of explanation, so the present disclosure is not necessarily limited to that which is shown. In the drawing, the thickness may be enlarged to clearly express various suitable layers and areas. And in the drawings, for convenience of explanation, the thicknesses of some layers and regions may be exaggerated.

Additionally, when a part of a layer, membrane, region, or plate is said to be “above” or “on” another part, this includes not only embodiments in which it is “directly above” another part, but also embodiments in which there is another part in between. In contrast, when an element is referred to as being “directly on” another element, there are no intervening elements present. In addition, being “above” or “on” a reference portion means being disposed above or below the reference portion, and does not necessarily mean being disposed “above” or “on” it in the direction opposite to gravity.

In addition, throughout the specification, if (e.g., when) a part is said to “comprise,” “include,” and/or “have” a certain component (e.g., a feature, a number, a step, an act, a task, an element, and/or a (e.g., any suitable) combination thereof), this may refer to that it may further include other components (e.g., a feature, a number, a step, an act, a task, an element, and/or a (e.g., any suitable) combination thereof) rather than excluding other components, unless specifically stated to the contrary.

In addition, throughout the specification, if (e.g., when) a reference is made to “on a plane,” this may refer to if (e.g., when) the target portion is viewed from above. If (e.g., when) a reference is made to “in cross-section,” this may refer to if (e.g., when) a cross-section of the target portion is cut vertically and viewed from the side of the target portion.

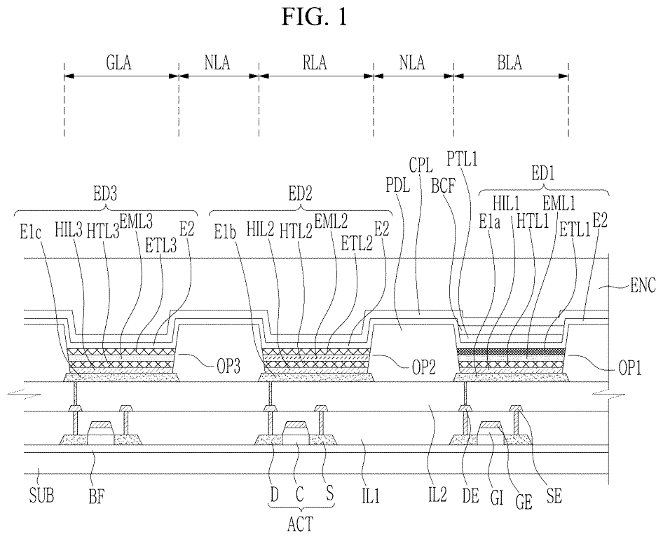

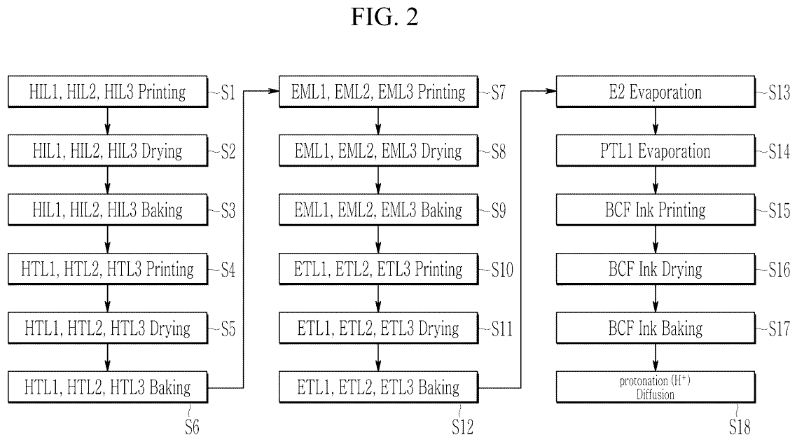

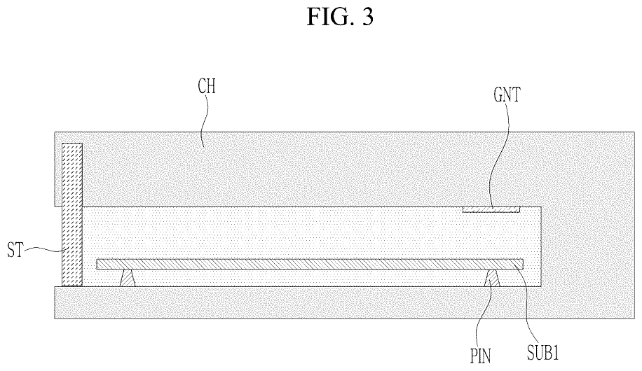

Hereinafter, in one or more embodiments of the present disclosure, a display device will be described with reference to FIGS. 1-3. In one or more embodiments, FIG. 1 is a cross-sectional view of a display device, FIG. 2 is a flowchart of a method of manufacturing one or more components of a display device, and FIG. 3 is a schematic drawing of a chamber for manufacturing a display device.

In one or more embodiments, a display device will be described with reference to FIG. 1.

The display device may include a red light emitting region RLA, a green light emitting region GLA, and a blue light emitting region BLA. A non-light emitting region NLA may be between (e.g., disposed between) the red light emitting region RLA, the green light emitting region GLA, and the blue light emitting region BLA. Each of the light emitting regions (e.g., the red light emitting region, the green light emitting region, and the blue light emitting region) may correspond to a pixel.

For example, the blue light emitting region BLA, the red light emitting region RLA, and the green light emitting region GLA may correspond to blue pixels, red pixels, and green pixels, respectively. A shape and arrangement of each of the red light emitting region RLA, the green light emitting region GLA, and the blue light emitting region BLA may be modified in various suitable ways.

In one or more embodiments, a display device may include a substrate SUB. The substrate SUB may include a flexible material, such as plastic that may be bent, folded, and/or rolled, or may include a rigid substrate.

A buffer layer BF may be on (e.g., disposed on) the substrate SUB. In one or more embodiments, the buffer layer BF may not be provided. The buffer layer BF may include silicon nitride (SiNₓ), silicon oxide (SiO₂), and/or silicon oxynitride. The buffer layer BF may be between (e.g., disposed between) the substrate SUB and the semiconductor layer ACT, to block impurities from the substrate SUB (or reduce an amount of impurities that reach the substrate SUB) during the crystallization process to form polycrystalline silicon, thereby improving the properties of polycrystalline silicon and to flatten the substrate to relieve the stress on the semiconductor layer ACT formed on the buffer layer BF.

In one or more embodiments, a semiconductor layer ACT may be on (e.g., disposed on) the buffer layer BF. The semiconductor layer ACT may be made of polycrystalline silicon or an oxide semiconductor. The semiconductor layer ACT includes a channel region C, a source region S, and a drain region D. The source region S and the drain region D are respectively on both sides (e.g., two opposing sides) of the channel region C. The channel region C is an intrinsic semiconductor that is not doped with impurities, and the source region S and drain region D are impurity semiconductors that are doped with conductive impurities (e.g., electrically conductive impurities). The semiconductor layer ACT may be made of an oxide semiconductor, in which embodiment a protective layer may be added to protect the oxide semiconductor material, which is vulnerable to external environments such as high temperature.

In one or more embodiments, a gate insulating layer GI may be on (e.g., disposed on) the semiconductor layer ACT. The gate insulating layer GI may be a single layer or multiple layers containing at least one selected from silicon nitride (SiNₓ), silicon oxide (SiO₂), and silicon oxynitride.

In one or more embodiments, a gate electrode GE, which is on the gate insulating layer GI, may include any one of copper (Cu), copper alloy, aluminum (Al), aluminum alloy, molybdenum (Mo), and/or molybdenum alloy. The gate electrode GE may be a multilayer in which metal layers are stacked.

In one or more embodiments, a interlayer insulating layer IL1 may be on (e.g., disposed on) the gate electrode GE and the gate insulating layer GI. The interlayer insulating layer IL1 may include silicon nitride (SiNₓ), silicon oxide (SiO₂), and/or silicon oxynitride. Openings exposing the source region S and drain region D may be in (e.g., disposed in) the interlayer insulating layer IL1.

In one or more embodiments, a source electrode SE and a drain electrode DE may be on (e.g., disposed on) the interlayer insulating layer IL1. The source electrode SE and drain electrode DE are respectively connected to the source region S and drain region D of the semiconductor layer ACT through an opening formed in the interlayer insulating layer IL1.

In one or more embodiments, a protective layer IL2 may be on (e.g., disposed on) the interlayer insulating layer IL1, the source electrode SE, and the drain electrode DE. The protective layer IL2 covers and flattens the interlayer insulating layer IL1, the source electrode SE, and the drain electrode DE, so that the first electrodes E1a, E1b, E1c may be formed on the protective layer IL2 without a step. This protective layer IL2 may be made of an organic material such as polyacrylate resin and/or polyimide resin, and/or a laminated layer of an organic material and an inorganic material.

In one or more embodiments, the first electrodes E1a, E1b, E1c may be on (e.g., disposed on) the protective layer IL2. The first electrodes E1a, E1b, E1c may be connected to the drain electrode DE through an opening in the protective layer IL2.

In one or more embodiments, the drive transistor, which may include a gate electrode GE, a semiconductor layer ACT, a source electrode SE, and a drain electrode DE, may be connected to the first electrode E1a, E1b, E1c to supply drive current to each light emitting element ED. In one or more embodiments, in addition to the driving transistor shown in FIG. 1, the display device may include a switching transistor connected to a data line and that transmits a data voltage in response to a scan signal. The display device may further include a compensation transistor that compensates for the threshold voltage of the transistor.

In one or more embodiments, a partition wall PDL may be on (e.g., disposed on) the protective layer IL2 and the first electrodes E1a, E1b, E1c. The partition wall PDL may have pixel openings OP1, OP2, and OP3 that overlap the first electrodes E1a, E1b, E1c and define an emitting region. The partition wall PDL may contain an organic material such as polyacrylates resin and/or polyimides resin, and/or a silica-based inorganic material. The pixel openings OP1, OP2, OP3 may have a planar shape substantially similar to that of the first electrodes E1a, E1b, E1c, and may have a diamond or octagonal shape similar to a diamond in plan, but may have any shape, such as, but not limited to, a square, a polygon, and/or the like.

In one or more embodiments, a first light emitting element ED1 may overlap the blue light emitting region BLA, a second light emitting element ED2 may overlap the red light emitting region RLA, and the third light emitting element ED3 may overlap the green light emitting region GLA.

In one or more embodiments, the first light emitting element ED1 may include a first electrode E1a, a first hole injection layer HIL1, a first hole transport layer HTL1, a first light emitting layer EML1, a first electron transport layer ETL1, and a second electrode E2.

In one or more embodiments, the second light emitting element ED2 may include a first electrode E1b, a second hole injection layer HIL2, a second hole transport layer HTL2, a second light emitting layer EML2, a second electron transport layer ETL2, and a second electrode E2.

In one or more embodiments, the third light emitting element ED3 may include a first electrode E1c, a third hole injection layer HIL3, a third hole transport layer HTL3, a third light emitting layer EML3, a third electron transport layer ETL3, and a second electrode E2.

In one or more embodiments, a partition wall PDL may be between (e.g., disposed between) the blue light emitting region BLA, the red light emitting region RLA, and/or the green light emitting region GLA. The partition wall PDL may include a first opening OP1 overlapping the blue light emitting region BLA, a second opening OP2 overlapping the red light emitting region RLA, and a third opening OP3 overlapping the green light emitting region GLA.

In one or more embodiments, the first opening OP1 and the first electrode E1a of the first light emitting region ED1 may overlap, and the second opening OP2 and the first electrode E1b of the second light emitting region ED2 may overlap, and the third opening OP3 and the first electrode E1c of the third light emitting element ED3 may overlap. At least a portion of the first electrode E1a of the first light emitting element ED1, the first electrode E1b of the second light emitting element ED2, and the first electrode E1c of the third light emitting element ED3 may overlap the partition wall

PDL. With respect to the partition wall PDL, the first electrode E1a of the first light emitting element ED1, the first electrode E1b of the second light emitting element ED2, and the first electrode E1c of the third light emitting element ED3 may be spaced apart from (separated from) each other.

In one or more embodiments, the first hole injection layer HIL1 may be on (e.g., disposed on) the first electrode E1a of the first light emitting element ED1, the second hole injection layer HIL2 may be on (e.g., disposed on) the first electrode E1bof the second light emitting element ED2, and the third hole injection layer HIL3 may be on (e.g., disposed on) the first electrode E1c of the third light emitting element ED3. The first hole injection layer HIL1, the second hole injection layer HIL2, and the third hole injection layer HIL3 may be spaced apart from (separated from) each other with respect to the partition wall PDL.

In one or more embodiments, the first hole injection layer HIL1 may be in (e.g., disposed in) the first opening OP1, the second hole injection layer HIL2 may be in (e.g., disposed in) the second opening OP2, and the third hole injection layer HIL3 may be in (e.g., disposed in) the third opening OP3. Each of the first hole injection layer HIL1, the second hole injection layer HIL2, and the third hole injection layer HIL3 may be formed through an inkjet process.

In one or more embodiments, the first hole injection layer HIL1, the second hole injection layer HIL2, and the third hole injection layer HIL3 may include the same material, but are not limited thereto and may include different materials.

In one or more embodiments, each of the first hole injection layer HIL1, the second hole injection layer HIL2, and the third hole injection layer HIL3 may include a hole injection material. Hole injection materials may include phthalocyanine compounds such as copper phthalocyanine; DNTPD(N,N′-diphenyl-N,N′-bis-[4-(phenyl-m-tolyl-amino)-phenyl]-biphenyl-4,4′-diamine), m-MTDATA(4,4′,4\″-[tris(3-methylphenyl)phenylamino]triphenylamine), TDATA(4,4′4\″-Tris (N,N-diphenylamino)triphenylamine), 2-TNATA(4,4′,4\″-tris{N,-(2-naphthyl)-N-phenylamino}-triphenylamine), PEDOT/PSS (Poly(3,4-ethylenedioxythiophene)/Poly(4-styrenesulfonate)), PANI/DBSA(Polyaniline/Dodecylbenzenesulfonic acid), PANI/CSA (Polyaniline/Camphor sulfonic acid), PANI/PSS (Polyaniline/Poly(4-styrenesulfonate)), NPB (N,N′-di(naphthalene-I-yl)-N,N′-diphenyl-benzidine), NPD (N,N′-Di(1-naphthyl)-N,N′-diphenyl-(1,1′-biphenyl)-4,4′-diamine), polyether ketone containing triphenylamine (TPAPEK), 4-Isopropyl-4′-methyldiphenyliodonium [Tetrakis(pentafluorophenyl)borate], HAT-CN(dipyrazino[2,3-f: 2′,3′-h] quinoxaline-2,3,6,7,10,11-hexacarbonitrile), and/or the like.

In one or more embodiments, The first hole transport layer HTL1 may be on (e.g., disposed on) the first hole injection layer HIL1, the second hole transport layer HTL2 may be on (e.g., disposed on) the second hole injection layer HIL2, and the third hole transport layer HTL3 may be on (e.g., disposed on) the third hole injection layer HIL3. The first hole transport layer HTL1, the second hole transport layer HTL2, and the third hole transport layer HTL3 may be spaced apart from (separated from) each other with respect to the partition wall PDL. The first hole transport layer HTL1 may be in (e.g., disposed in) the first opening OP1, the second hole transport layer HTL2 may be in (e.g., disposed in) the second opening OP2, and the third hole transport layer HTL3 may be in (e.g., disposed in) the third opening OP3.

In one or more embodiments, Each of the first hole transport layer HTL1, the second hole transport layer HTL2, and the third hole transport layer HTL3 may be formed through an inkjet process. The first hole transport layer HTL1, the second hole transport layer HTL2, and the third hole transport layer HTL3 may include the same material, but are not limited thereto and may include different materials.

In one or more embodiments, Each of the first hole transport layer HTL1, the second hole transport layer HTL2, and the third hole transport layer HTL3 may include a hole transport material. Hole transport materials include carbazole-based derivatives such as N-phenylcarbazole and polyvinylcarbazole, fluorene-based derivatives, and TPD (N,N′-bis(3-methylphenyl)-N,N′-diphenyl-[Triphenylamine derivatives such as 1,1-biphenyl]-4,4′-diamine), TCTA (4,4′,4\″-tris(N-carbazolyl)triphenylamine), NPB (N,N′-di(naphthalene-I-yl)-N,N′-diphenyl-benzidine), TAPC(4,4′-Cyclohexylidene bis[N,N-bis(4-methylphenyl)benzenamine]), HMTPD(4,4′-Bis[N,N′-(3-tolyl)amino]-3,3′-dimethylbiphenyl), mCP(1,3-Bis(N-carbazolyl)benzene), CzSi(9-(4-tert-Butylphenyl)-3,6-bis(triphenylsilyl)-9H-carbazole), m-MTDATA (4,4′,4\″-[tris(3-methylphenyl)phenylamino] triphenylamine), and/or the like.

In one or more embodiments, The first light emitting layer EML1 may be on (e.g., disposed on) the first hole transport layer HTL1, the second light emitting layer EML2 may be on (e.g., disposed on) the second hole transport layer HTL2, and the third light emitting layer EML3 may be on (e.g., disposed on) the third hole transport layer HTL3. The first light emitting layer EML1, the second light emitting layer EML2, and the third light emitting layer EML3 may be spaced apart from (separated from) each other with respect to the partition wall PDL. The first light emitting layer EML1 may be in (e.g., disposed in) the first opening OP1, the second light emitting layer EML2 may be in (e.g., disposed in) the second opening OP2, and the third light emitting layer EML3 may be in (e.g., disposed in) the third opening OP3. Each of the first light emitting layer EML1, the second light emitting layer EML2, and the third light emitting layer EML3 may be manufactured through an inkjet process.

In one or more embodiments, The first light emitting layer EML1, the second light emitting layer EML2, and the third light emitting layer EML3 may emit light of different colors.

In one or more embodiments, The first light emitting layer EML1 may emit blue light. The first light emitting layer EML1 may include an organic material, particularly a low-molecular organic material and/or a high-molecular organic material, such as poly 3,4-ethylenedioxythiophene (PEDOT).

In one or more embodiments, The second light emitting layer EML2 may emit red light. The second light emitting layer EML2 may include a first quantum dot. The third light emitting layer EML3 may emit green light. The third light emitting layer EML3 may include a second quantum dot.

Hereinafter, quantum dots including a first quantum dot and a second quantum dot will be described in more detail.

In this specification, quantum dots (hereinafter also referred to as semiconductor nanocrystals) may include Group II-VI compounds, Group III-V compounds, Group IV compounds, Group IV elements or compounds, Group I-III-VI compounds, Group II-III-VI compounds, Group I-II-IV-VI compounds, and/or a combination thereof.

The Group II-VI compounds may be selected from among the group including (e.g., consisting of) binary compounds, such as CdSe, CdTe, ZnS, ZnSe, ZnTe, ZnO, HgS, HgSe, HgTe, MgSe, MgS, and/or mixtures thereof, ternary compounds selected from among the group including (e.g., consisting of) AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and/or mixtures thereof, and/or quaternary compounds selected from among the group including (e.g., consisting of) HgZnTeS, CdZnSeS, CdZnSeTe, CdZnSTe, CdHgSeS, CdHgSeTe, CdHgSTe, HgZnSeS, HgZnSeTe, HgZnSTe, and/or mixtures thereof. In one or more embodiments, the Group II-VI compounds may further include a Group III metal.

The Group III-V compounds may include binary compounds selected from among the group including (e.g., consisting of) GaN, GaP, GaAs, GaSb, AlN, AlP, AlAs, AlSb, InN, InP, InAs, InSb, and/or mixtures thereof, a ternary compound selected from among the group including (e.g., consisting of) GaNP, GaNAs, GaNSb, GaPAs, GaPSb, AlINP, AlNAs, AlNSb, AlPAs, AlPSb, InGaP, InNP, InNAs, InNSb, InPAs, InZnP, InPSb, and/or mixtures thereof, and/or a quaternary compound selected from among the group including (e.g., consisting of) GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, and/or mixtures thereof. The Group III-V compounds may further include a Group II metal (e.g., InZnP).

The Group IV-VI compounds may include binary compounds selected from among the group including (e.g., consisting of) SnS, SnSe, SnTe, PbS, PbSe, PbTe, and/or mixtures thereof, a ternary compound selected from among the group including (e.g., consisting of) SnSeS, SnSeTe, SnSTe, PbSeS, PbSeTe, PbSTe, SnPbS, SnPbSe, SnPbTe, and/or mixtures thereof, and/or a quaternary element compound selected from among the group including (e.g., consisting of) SnPbSSe, SnPbSeTe, SnPbSTe, and/or mixtures thereof.

The Group IV element or compound may be selected from among the group including (e.g., consisting of) Si, Ge, and a combination thereof, and may be selected from among the group including (e.g., consisting of) SiC, SiGe, and/or a combination thereof, but is not limited thereto.

Examples of Group I-III-VI compounds may include, but are not limited to, CuInSe₂, CuInS₂, CuInGaSe, and/or CuInGaS. Examples of Group I-II-IV-VI compounds may include, but are not limited to, CuZnSnSe, and/or CuZnSnS. The Group IV element or compound may be a single element selected from among the group including (e.g., consisting of) Si, Ge, and/or mixtures thereof, and a binary compound selected from among the group including (e.g., consisting of) SiC, SiGe, and/or mixtures thereof.

The Group II-III-VI compounds may include ZnGaS, ZnAlS, ZnInS, ZnGaSe, ZnAlSe, ZnInSe, ZnGaTe, ZnAlTe, ZnInTe, ZnGaO, ZnAlO, ZnInO, HgGaS, HgAlS, HgInS, HgGaSe, HgAlSe, HgInSe, HgGaTe, HgAlTe, HgInTe, MgGaS, MgAlS, MgInS, MgGaSe, MgAlSe, MgInSe, and/or combinations thereof, but is not limited thereto.

The Group I-II-IV-VI compound may be selected from among CuZnSnSe and/or CuZnSnS, but is not limited thereto.

In one or more embodiments, the quantum dots may not include (e.g., may exclude) cadmium. Quantum dots may include semiconductor nanocrystals based on

Group III-V compounds including indium and/or phosphorus. The Group III-V compound may further include zinc. Furthermore, quantum dots may include semiconductor nanocrystals based on Group II-VI compounds including chalcogen elements (e.g., sulfur, selenium, tellurium, and/or combinations thereof) and/or zinc.

In one or more embodiments, in a quantum dot, the above-mentioned binary, ternary, and/or monovalent compounds may exist in a particle (e.g., a form of a particle) at a substantially uniform concentration, or may exist in the same particle with a partially different concentration distribution. Additionally, one quantum dot may have a core/shell structure (e.g., a structure of a core being surrounded by a shell) surrounding (around) other quantum dots. The interface between the core and the shell may have a concentration gradient in which the concentration of elements present in the shell decreases along a direction toward a center of the core.

In one or more embodiments, the quantum dot may have a core/shell structure including a core containing the above-described nanocrystals and a shell surrounding (around) the core. The shell of the quantum dot may serve as a protective layer to maintain semiconductor properties by preventing or reducing chemical denaturation of the core and/or as a charging layer to impart electrophoretic properties to the quantum dot. The shell may be single-layered or multi-layered. The interface between the core and the shell may have a concentration gradient in which the concentration of elements presented in the shell decreases along the direction toward the center of the core. Examples of the shell of the quantum dot may include metal and/or non-metal oxides, semiconductor compounds, and/or combinations thereof.

For example, the oxide of the metal or non-metal may be a binary

compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, or MgAl₂O₄, CoFe₂O₄, NiFe₂O₄, and/or CoMn₂O₄, but the present disclosure is not limited thereto.

In addition, the semiconductor compounds may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like, but the present disclosure is not limited thereto.

In one or more embodiments, the interface between the core and the shell may have a concentration gradient in which the concentration of elements presented in the shell decreases along the direction toward the center of the core. Additionally, the semiconductor nanocrystal may have a structure including a single semiconductor nanocrystal core and a multi-layered shell surrounding it. In one or more embodiments, the multi-layered shell may have two or more layers, such as two, three, four, five or more layers. The two adjacent layers of the shell may have a single composition or different compositions. In a multi-layered shell, each layer may have a composition that changes along the radius.

In one or more embodiments, the quantum dots may have a full width of half maximum FWHM of the emitting wavelength spectrum of about 45 nm or less, for example, about 40 nm or less, about 30 nm or less, and within this range, color purity and/or color reproducibility may be improved. Additionally, because the light emitted through or from these quantum dots is emitted in all (or substantially all) directions, the optical viewing angle may be improved.

In one or more embodiments, the quantum dots may have different energy band gaps between the shell material and the core material. For example, the energy band gap of the shell material may be larger than that of the core material. In some embodiments, the energy band gap of the shell material may be smaller than that of the core material. The quantum dots may have a multi-layered shell. In the multi-layered shell, the energy band gap of the outer layer may be larger than that of the inner layer (e.g., the layer close to the core). In the multi-layered shell, the energy band gap of the outer layer may be smaller than that of the inner layer.

The quantum dots may control absorption/emission of wavelengths by adjusting their composition and size. The maximum light emitting peak wavelength of a quantum dot may range from ultraviolet to infrared wavelengths or longer.

The quantum dots may have a quantum efficiency of at least about 10%, at least about 30%, at least about 50%, at least about 60%, at least about 70%, at least about 90%, or 100%. The quantum dots may have a relatively narrow spectrum. The quantum dots may have a full width at half maximum of the emitting wavelength spectrum of, for example, about 50 nm or less, such as about 45 nm or less, about 40 nm or less, or about 30 nm or less.

The quantum dots may have a particle size of about 1 nm or more and about 100 nm or less. The size of a particle may refer to the diameter of the particle or the diameter converted by assuming a spherical shape (e.g., a substantially spherical shape) from a two-dimensional image obtained by a transmission electron microscope analysis. The quantum dots may have a size of about 1 nm to about 20 nm, for example, 2 nm or more, 3 nm or more, or 4 nm or more and 50 nm or less, 40 nm or less, 30 nm or less, 20 nm or less, 15 nm or less, such as 10 nm or less. The shape of the quantum dots is not particularly limited. For example, the shape of the quantum dots may include, but is not limited to, a sphere, polyhedron, pyramid, multipod, square, cuboid, nanotube, nanorod, nanowire, nanosheet, and/or a combination thereof.

In one or more embodiments, the quantum dots may be commercially available or may be suitably or appropriately synthesized. The particle size of the quantum dots may be controlled relatively freely during colloid synthesis, and the particle size may also be adjusted uniformly (e.g., substantially uniformly).

In one or more embodiments, the quantum dots may include organic ligands (e.g., having hydrophobic and/or hydrophilic moieties). The organic ligand residue may be bound to a surface of the quantum dot. The organic ligands may include RCOOH, RNH₂, R₂NH, R₃N, RSH, R₃PO, R₃P, ROH, RCOOR, RPO(OH)₂, RHPOOH, R2POOH, and/or a combination thereof, where each R may be independently C3 to C40 (e.g., C5 or more and C24 or less), a substituted or unsubstituted alkenyl, a substituted or unsubstituted aliphatic hydrocarbon group of C3 to C40, (e.g., C6 or more and C20 or less), a substituted or unsubstituted aromatic hydrocarbon group of C6 to C40 (e.g., C6 or more and C20 or less), and/or a combination thereof.

Examples of organic ligands may include thiol compounds, such as methane thiol, ethane thiol, propane thiol, butane thiol, pentane thiol, hexane thiol, octane thiol, dodecane thiol, hexadecane thiol, octadecane thiol, and/or benzyl thiol; amines, such as methane amine, ethane amine, propane amine, butane amine, pentyl amine, hexyl amine, octyl amine, nonyl amine, decyl amine, dodecyl amine, hexadecyl amine, octadecyl amine, dimethyl amine, diethyl amine, dipropyl amine, tributylamine, trioctylamine, and/or the like; carboxylic acid compounds, such as methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, and/or benzoic acid; phosphine compounds, such as methyl phosphine, ethyl phosphine, propyl phosphine, butyl phosphine, pentyl phosphine, diphenyl phosphine, triphenyl phosphine, octyl phosphine, dioctyl phosphine, tributyl phosphine, trioctyl phosphine, and/or the like; phosphine oxide compounds, such as methyl phosphine oxide, ethyl phosphine oxide, propyl phosphine oxide, butyl phosphine oxide, pentyl phosphine oxide, tributyl phosphine oxide, diphenyl phosphine oxide, triphenyl phosphine oxide, octyl phosphine oxide, dioctyl phosphine oxide, trioctyl phosphine oxide compound, and/or the like. Examples of acid compounds may include but may not be limited to C5 to C20 alkyl phosphinic acids, such as hexylphosphinic acid, octylphosphinic acid, dodecane phosphinic acid, tetradecane phosphinic acid, hexadecane phosphinic acid, and/or octadecane phosphinic acid, and/or C5 to C20 alkyl phosphonic acid. Quantum dots may include hydrophobic organic ligands alone and/or in a mixture of one or more types or kinds of hydrophobic organic ligands. The hydrophobic organic ligand may not contain (may exclude) a photopolymerizable residue (e.g., an acrylate group and/or a methacrylate group).

Referring again to FIG. 1, the first electron transport layer ETL1 may be on (e.g., positioned on) the first light emitting layer EML1, the second electron transport layer ETL2 may be on (e.g., positioned on) the second light emitting layer EML2, and the third electron transport layer ETL3 may be on (e.g., positioned on) the third light emitting layer EML3. The first electron transport layer ETL1, the second electron transport layer ETL2, and the third electron transport layer ETL3 may be spaced apart with respect to (e.g., separated from) the partition wall PDL. The first electron transport layer ETL1 may be in (e.g., disposed in) the first opening OP1, the second electron transport layer ETL2 may be in (e.g., disposed in) the second opening OP2, and the third electron transport layer ETL3 may be in (e.g., disposed in) the third opening OP3.

In one or more embodiments, the first electron transport layer ETL1, the second electron transport layer ETL2, and the third electron transport layer ETL3 may each be formed through an inkjet process. The second electron transport layer ETL2 and the third electron transport layer ETL3 may include the same electron transport material. The first electron transport layer ETL1 may include an electron transport material different from the second electron transport layer ETL2 and the third electron transport layer ETL3.

In one or more embodiments, the first electron transport layer ETL1 may include a triazine-based compound and/or an anthracene-based compound. However, by way of example but not by way of limitation, the electronic transport material may include, for example, Alq₃ (Tris(8-hydroxyquinolinato)aluminum), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-ylphenyl)-9,10-dinaphthylanthracene, TPBi(1,3,5-tris(1-phenyl-1H-benzo[d]imidazol-2-yl)benzene), BCP (2,9-Dimethyl-4,7-diphenyl-1,10-phenanthroline), Bphen(4,7-Diphenyl-1,10-phenanthroline), TAZ(3-(4-Biphenylyl)-4-phenyl-5-tert-butylphenyl-1,2,4-triazole), NTAZ(4-(Naphthalen-1-yl)-3,5-diphenyl-4H-1,2,4-triazole), tBu-PBD(2-(4-Biphenylyl)-5-(4-tert-butylphenyl)-1,3,4-oxadiazole), BAlq(Bis(2-methyl-8-quinolinolato-N1,O8)-(1,1′-Biphenyl-4-olato)aluminum), Bebq2(berylliumbis(benzoquinolin-10-olate), ADN(9,10-di (naphthalene-2-yl)anthracene), TSPO1(diphenyl(4-(triphenylsilyl)phenyl)phosphine oxide), TPM-TAZ (2,4,6-Tris(3-(pyrimidin-5-yl)phenyl)-1,3,5-triazine), and/or mixtures thereof. In embodiments, the second electron transport layer ETL2 and the third electron transport layer ETL3 may include ZnMgO.

In one or more embodiments, the second electrode E2 may be on (e.g., positioned on) the first electron transport layer ETL1, the second electron transport layer ETL2, and the third electron transport layer ETL3. In one or more embodiments, the second electrode E2 may be continuously provided across the blue light emitting region BLA, the red light emitting region RLA, the green light emitting region GLA, and the non-light emitting region NLA. The second electrode E2 may receive a common voltage through a common voltage transmitter in the non-display area.

In one or more embodiments, the first electrode E1a, E1b, E1c may be an anode, which is a hole injection electrode, and the second electrode E2 may be a cathode, which is an electron injection electrode. However, by way of example but not by way of limitation, and depending on how the display device is driven, the first electrodes E1a, E1b, E1c may be a cathode, and the second electrode E2 may be an anode.

In one or more embodiments, a capping layer CPL may be on (e.g., positioned on) the second electrode E2. In one or more embodiments, the capping layer CPL may be continuously provided across the blue light emitting region BLA, the red light emitting region RLA, the green light emitting region GLA, and the non-light emitting region NLA.

In one or more embodiments, in the blue light emitting region BLA, the first passivation layer PTL1 may be between (e.g., positioned between) the second electrode E2 and the capping layer CPL. The first passivation layer PTL1 may include an inorganic material, for example, at least one of silicon nitride, silicon nitride, and/or silicon oxide. However, the first passivation layer PTL1 may not be limited thereto and may include a high-transmittance material including a high layer density, such as a metal and/or organometallic material. The first passivation layer PTL1 protects the first light emitting layer EML1 in an acid treatment process to be described in more detail herein below, and may improve the reliability of the display device.

In one or more embodiments, the first passivation layer PTL1 may be formed through a patterning process and/or an inkjet process. The first passivation layer PTL1 may be within (e.g., disposed within) the first opening OP1 included in the partition wall PDL. In some embodiments, the first passivation layer PTL1 may overlap at least a portion of the first opening OP1. In some embodiments, the first passivation layer PTL1 may overlap at least a portion of the upper surface of the partition wall PDL.

In one or more embodiments, the first passivation layer PTL1 may be in (e.g., disposed in) the blue light emitting region BLA and may not be in (e.g., disposed in) the red light emitting region RLA and the green light emitting region GLA. The first passivation layer PTL1 may overlap the first emitting layer EML1 and may be spaced apart from (separated from) the second emitting layer EML2 and the third emitting layer EML3. The first passivation layer PTL1 may overlap the first light emitting element ED1 and may be spaced apart from (separated from) the second light emitting element ED2 and the third light emitting element ED3.

In one or more embodiments, a blue color filter BCF may be on (e.g., disposed on) the first passivation layer PTL1. The blue color filter BCF may be formed through an inkjet process and a low-temperature curing process. The blue color filter BCF may overlap the first emitting layer EML1 and may be spaced apart from (separated from) the second emitting layer EML2 and the third emitting layer EML3. The blue color filter BCF may overlap the first light emitting element ED1 and may be spaced apart from (separated from) the second light emitting element ED2 and the third light emitting element ED3. The blue color filter BCF protects the first emitting layer EML1, reduces diffuse reflection of blue light, and provides blue light having improved color purity.

In one or more embodiments, the blue color filter BCF may contact the capping layer CPL, and the first passivation layer PTL1 may contact the second electrode E2.

In one or more embodiments, the encapsulation layer ENC may be on (e.g., disposed on) the capping layer CPL. The encapsulation layer ENC may seal the display layer by covering not only the top surface but also the side surfaces of the display layer including the light emitting elements ED1, ED2, ED3.

Because the light emitting element is relatively vulnerable to moisture and oxygen, the encapsulation layer ENC may seal the display layer and may block or reduce the inflow of external moisture and oxygen. The encapsulation layer ENC may include a plurality of layers, and may be formed as a composite layer including both an inorganic layer and an organic layer. Furthermore, the encapsulation layer ENC may be a triple layer in which a first inorganic layer, an organic layer, and a second inorganic layer are formed sequentially.

Referring to FIG. 1 and FIG. 2 discussed above, a manufacturing process of the display device in one or more embodiments will be described.

First, a plurality of transistors is formed on the substrate SUB, and a partition wall PDL having openings OP1, OP2, and OP3 is formed on the protective layer IL2. The first ink for forming hole injection layers HIL1, HIL2, HIL3 is discharged into each of the openings OP1, OP2, OP3 of the partition wall PDL (S1). Then, the discharged first ink is dried (S2) and baked (S3) to form the hole injection layers HIL1, HIL2, HIL3. Although this specification describes the first ink for convenience, each of the hole injection layers HIL1, HIL2, HIL3 may include the same hole injection material or may include different hole injection materials.

Next, a second ink is discharged to form hole transport layers HTL1, HTL2, HTL3 on the hole injection layers HIL1, HIL2, HIL3 (S4). Then, the discharged second ink is dried (S5) and baked (S6) to form the hole transport layers HTL1, HTL2, HTL3. Although this specification describes the second ink for convenience, each of the hole transport layers HTL1, HTL2, HTL3 may include the same hole transport material or different hole transport materials.

Next, a third ink is discharged to form the light emitting layers EML1, EML2, EML3 on the hole transport layers HTL1, HTL2, HTL3 (S7). Then, the third ink is dried (S8) and baked (S9) to form the light emitting layers EML1, EML2, EML3. Although this specification describes the third ink for convenience, each of the light emitting layers EML1, EML2, EML3 may include different materials as described above.

Then, the fourth ink is discharged to form the electron transport layers ETL1, ETL2, ETL3 on the light emitting layers EML1, EML2, EML3 (S10). The fourth ink is dried (S11) and baked (S12) to form the electron transport layers ETL1, ETL2, ETL3. Although this specification describes the fourth ink for convenience, the electron transport layers ETL1, ETL2, ETL3 may include different materials as described above. The second electron transport layer ETL2 and the third electron transport layer ETL3 may include ZnMgO, and the first electron transport layer ETL1 may include other materials.

Afterwards, the second electrode E2 is formed on the electron transport layers ETL1, ETL2, ETL3 through a deposition process (S13). Then, the first passivation layer PTL1 is formed on the second electrode E2 overlapping the blue light emitting region BLA through a deposition process (S14). Afterwards, ink for manufacturing a blue color filter is printed on the first passivation layer PTL1 (S15), dried (S16), and baked (S17) to provide a blue color filter BCF.

Then, an acid treatment process is performed on the substrate SUB (S18). The acid treatment process in one or more embodiments may be performed within the chamber shown in FIG. 3.

Looking at a chamber CH shown in FIG. 3, a stacked structure SUB1 may be able to enter and exit through a shutter ST. As described with reference to FIGS. 1-2, the stacked structure SUB1 refers to a structure in which all components except the capping layer CPL in FIG. 1 are stacked. The chamber CH may be made of stainless steel (SUS) and/or fluorine-based plastic material that may withstand acid corrosion.

The stacked structure SUB1 may be charged into the chamber CH through the open shutter ST. The stacked structure SUB1 may be supported by a pin PIN within the chamber CH. The height of the stacked structure SUB1 may be adjusted using a pin PIN.

An acid generator GNT that maintains a constant acid concentration may be in (e.g., disposed in) the chamber CH. The stacked structure SUB1 may be placed in the above-described chamber CH for 10 to 20 minutes. If (e.g., when) exposed to an acidic atmosphere, the surface of ZnMgO included in the second and third electron transport layers may be modified. For example, the fumed acid flows into the second and third electron transport layers to heal defects in ZnMgO and improve the properties by modifying the surface of ZnMgO. If (e.g., when) defects in ZnMgO are cured, electron transfer efficiency is improved and the luminous efficiency of the light emitting element may thereby increase.

Additionally, in this acid treatment process, the first electron transport layer and the first light emitting layer that do not contain ZnMgO may be damaged by the acid. A damaged first light emitting layer may cause problems, such as lowering the efficiency of the blue light emitting element and shortening the lifespan of the device. However, the first passivation layer PTL1 and the blue color filter BCF in one or more embodiments may prevent or reduce the inflow of acid, thereby preventing or reducing damage to the first light emitting element and increasing reliability.

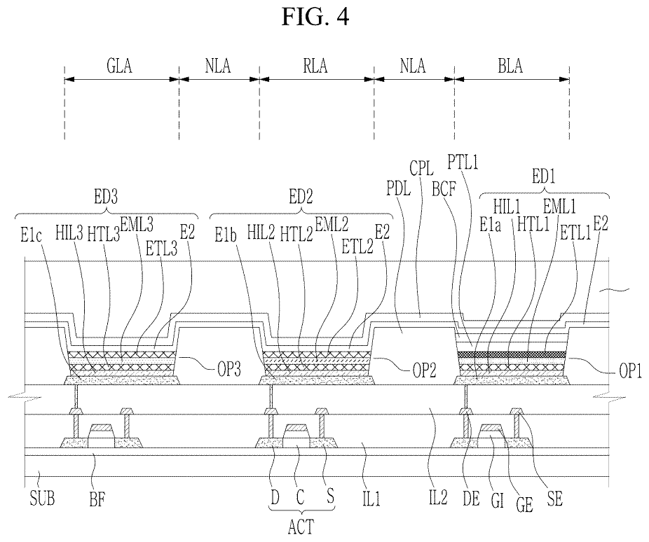

Hereinafter, a display device in one or more embodiments will be described with reference to FIGS. 4-9.

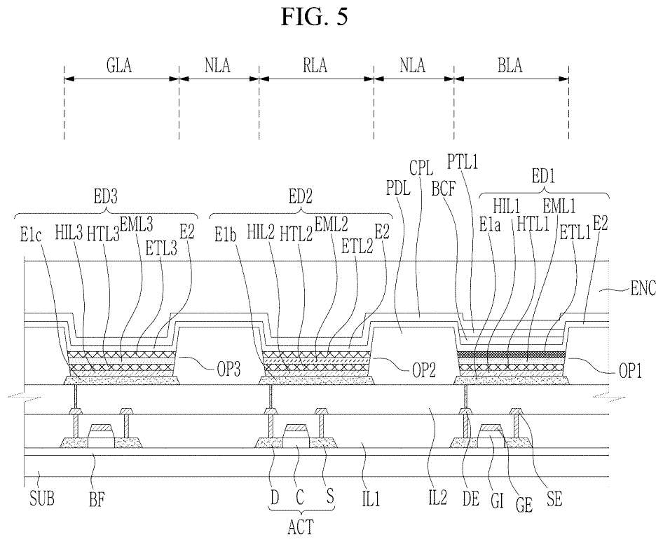

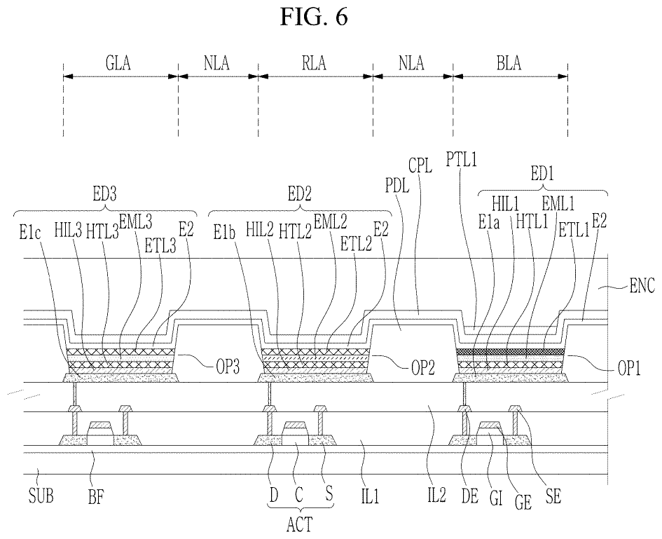

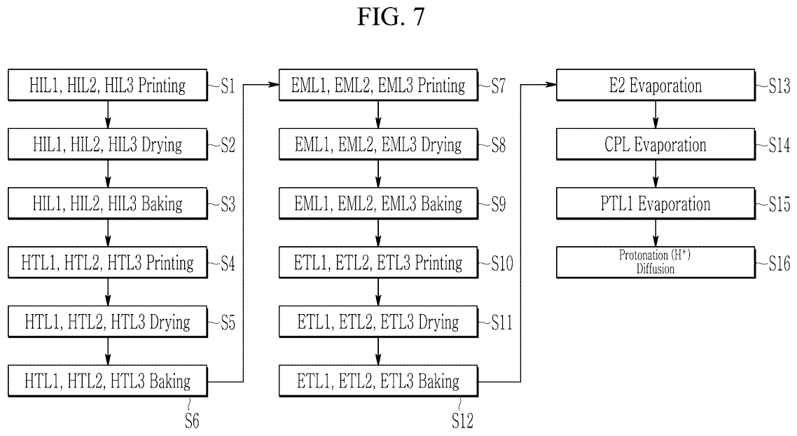

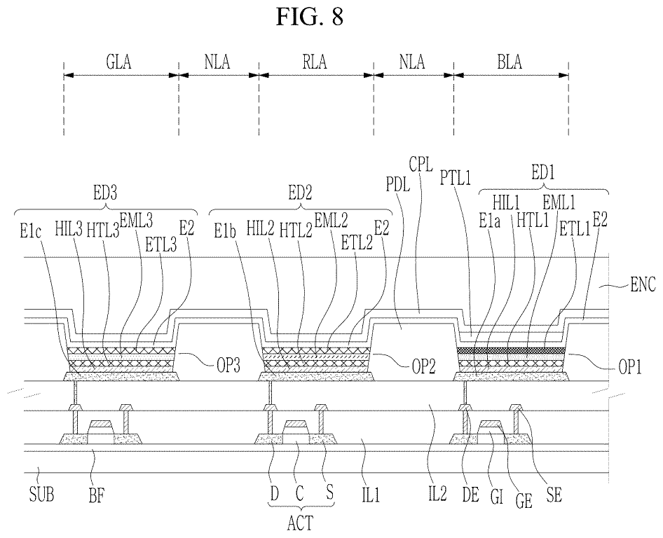

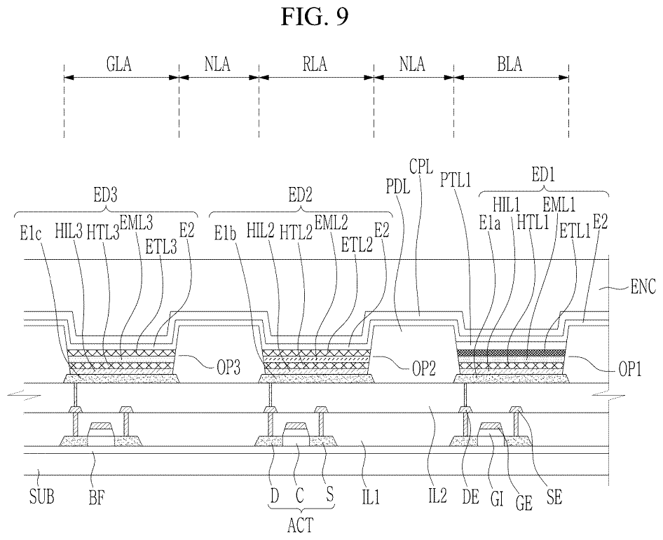

FIG. 4 and FIG. 5 are cross-sectional views of a display device in one or more embodiments, FIG. 6 is a cross-sectional view of a display device in one or more embodiments, FIG. 7 is is a flowchart of an embodiment of the manufacturing method, and FIGS. 8-9 are cross-sectional views of a display device in one or more embodiments. Descriptions of components that are the same as those described above may not be repeated here.

In one or more embodiments, referring to FIG. 4, in the display device, the first light emitting element ED1 may overlap the blue light emitting region BLA, the second light emitting element ED2 may overlap the red light emitting region RLA, the third light emitting element ED3 may overlap the green light emitting region GLA. In one or more embodiments, a stacked structure of the second light emitting element

ED2 and a stacked structure of the third light emitting element ED3 may be the same as the stacked structures of the second light emitting element ED2 and the third light emitting element ED3 shown in the embodiment of FIG. 1.

The first light emitting element ED1 includes the first electrode E1a, the first hole injection layer HIL1, the first hole transport layer HTL1, the first light emitting layer EML1, the first electron transport layer ETL1, and the second electrode E2.

Referring to FIG. 4, the first passivation layer PTL1 and the blue color filter BCF may be between (e.g., positioned between) the first electron transport layer ETL1 and the second electrode E2. The capping layer CPL may be on (e.g., positioned on) the second electrode E2. The capping layer CPL may be continuously provided across the blue light emitting region BLA, the red light emitting region RLA, the green light emitting region GLA, and the non-light emitting region NLA.

The first passivation layer PTL1 may include an inorganic material, for example, at least one of silicon nitride, silicon oxide, and/or silicon oxynitride. The first passivation layer PTL1 protects the first light emitting layer EML1 in an acid treatment process to be described in more detail and may improve the reliability of the display device. The first passivation layer PTL1 may be formed through a patterning process and/or an inkjet process.

The first passivation layer PTL1 may be within (e.g., disposed within) the first opening OP1 included in the partition wall PDL. The blue color filter BCF may be on (e.g., disposed on) the first passivation layer PTL1. The blue color filter BCF may be formed through an inkjet process and a low-temperature curing process. The blue color filter BCF protects the first light emitting layer EML1, reduces diffuse reflection of blue light, and provides blue light having improved color purity.

The blue color filter BCF may contact the second electrode E2, and the first passivation layer PTL1 may contact the first electron transport layer ETL1.

In one or more embodiments, referring to FIG. 5, a display device may include the blue color filter BCF and the first passivation layer PTL1 on the second electrode E2. The blue color filter BCF may contact the second electrode E2, and the first passivation layer PTL1 may contact the capping layer CPL.

In one or more embodiments, referring to FIG. 6, in the display device, the first light emitting region ED1 may overlap the blue light emitting region BLA, the second light emitting region ED2 may overlap the red light emitting region RLA, and the third light emitting element ED3 may overlap the green light emitting region GLA. In one or more embodiments, a stacked structure of the second light emitting element ED2 and a stacked structure of the third light emitting element ED3 may be the same as the stacked structures of the second light emitting element ED2 and the third light emitting element ED3 shown in the embodiment of FIG. 1.

The first light emitting element ED1 may include the first electrode E1a, the first hole injection layer HIL1, the first hole transport layer HTL1, the first light emitting layer EML1, the first electron transport layer ETL1, and the second electrode E2.

Referring to FIG. 6, the first passivation layer PTL1 may be on (e.g., disposed on) the capping layer CPL. The capping layer CPL may be continuously provided across the blue light emitting region BLA, the red light emitting region RLA, the green light emitting region GLA, and the non-light emitting region NLA.

The first passivation layer PTL1 may include an inorganic material, for example, at least one of silicon nitride, silicon oxide, and/or silicon oxynitride.

The first passivation layer PTL1 protects the first light emitting element ED1, especially the first light emitting layer EML1, in an acid treatment process to be described in more detail, and may improve the reliability of the display device.

The first passivation layer PTL1 may be formed through a patterning process or an inkjet process. The first passivation layer PTL1 may be on (e.g., disposed on) the partition wall PDL. The first passivation layer PTL1 may be formed along the steps of the capping layer CPL. The first passivation layer PTL1 may overlap at least a portion of the first opening OP1. The first passivation layer PTL1 may overlap at least a portion of the partition wall PDL.

The first passivation layer PTL1 may be in (e.g., disposed in) the blue light emitting region BLA, and may not be in (e.g., disposed in) the red light emitting region RLA, and/or the green light emitting region GLA. The first passivation layer PTL1 may overlap the first light emitting layer EML1 and may be spaced apart from (separated from) the second light emitting layer EML2 and the third emitting layer EML3. The first passivation layer PTL1 may overlap the first light emitting element ED1 and may be spaced apart from (separated from) the second light emitting element ED2 and the third light emitting element ED3.

With reference to FIGS. 6-7 discussed above, the manufacturing process of the display device in one or more embodiments will be described.

First, a plurality of transistors are formed on the substrate SUB, and the partition wall PDL having openings OP1, OP2, OP3 is formed on the protective layer IL2. The first ink for forming the hole injection layers HIL1, HIL2, HIL3 is discharged into each of the openings OP1, OP2, OP3 of the partition wall PDL (S1). Then, the discharged first ink is dried (S2) and baked (S3) to form the hole injection layers HIL1, HIL2, HIL3. Although shown here in the first ink for convenience, each of the hole injection layers HIL1, HIL2, HIL3 may include the same hole injection material or may include different hole injection materials.

Next, a second ink is discharged to form the hole transport layers HTL1, HTL2, HTL3 on the hole injection layers HIL1, HIL2, HIL3 (S4). Then, the discharged second ink is dried (S5) and baked (S6) to form the hole transport layers HTL1, HTL2, HTL3. Although shown here in the second ink for convenience, each of the hole transport layers HTL1, HTL2, HTL3 may include the same hole transport material or different hole transport materials.

Next, the third ink to form the light emitting layers EML1, EML2, EML3 on the hole transport layers HTL1, HTL2, HTL3 is discharged (S7), the third ink is then dried (S8) and baked (S9) to form the light emitting layers EML1, EML2, EML3. Although shown here in the third ink for convenience, each of the light emitting layers EML1, EML2, EML3 may include different materials as described above.

Then, the fourth ink is discharged to form the electron transport layers ETL1, ETL2, ETL3 on the light emitting layers EML1, EML2, EML3 (S10). The fourth ink is dried (S11) and baked (S12) to form the electron transport layers ETL1, ETL2, ETL3. Although shown here in the fourth ink for convenience, the electron transport layers ETL1, ETL2, ETL3 may include different materials as described above. The second electron transport layer ETL2 and the third electron transport layer ETL3 may include ZnMgO, and the first electron transport layer ETL1 may include other electron transport materials.

Afterwards, the second electrode E2 and the capping layer CPL are sequentially formed on the electron transport layers ETL1, ETL2, ETL3 through a deposition process (S13, S14). Then, the first passivation layer PTL1 is formed on the capping layer CPL overlapping the blue light emitting region BLA through a deposition process (S15). Afterwards, an acid treatment process is performed on the substrate SUB (S16). In one or more embodiments, the acid treatment process may be performed within the chamber previously shown in FIG. 3.

Next, in one or more embodiments, a display device will be described with reference to FIG. 8. In the display device according to the embodiment of FIG. 8, the first light emitting element ED1 may overlap the blue light emitting region BLA, the second light emitting element ED2 may overlap the red light emitting region RLA, and the third light emitting element ED3 may overlap the green light emitting region GLA. In one or more embodiments, a stacked structure of the second light emitting element ED2 and a stacked structure of the third light emitting element ED3 may be the same as the stacked structures of the second light emitting element ED2 and the third light emitting element ED3 in the embodiment of FIG. 6.

The first passivation layer PTL1 may be on (e.g., disposed on) the second electrode E2 in the blue light emitting region BLA. A capping layer CPL may be on (e.g., disposed on) the first passivation layer PTL1. The second electrode E2 and the capping layer CPL may be continuously provided across the blue light emitting region BLA, red light emitting region RLA, green light emitting region GLA, and non-light emitting region NLA.

The first passivation layer PTL1 may include an inorganic material, for example, at least one of silicon nitride, silicon oxide, and/or silicon oxynitride. The first passivation layer PTL1 protects the first light emitting region ED1, for example, the first light emitting layer EML1, in an acid treatment process to be described in more detail herein, and may improve the reliability of the display device.

The first passivation layer PTL1 may be in (e.g., disposed in) the blue light emitting region BLA and may not be in (e.g., disposed in) the red light emitting region RLA and/or the green light emitting region GLA. The first passivation layer PTL1 may overlap the first light emitting layer EML1 and may be spaced apart from (separated from) the second light emitting layer EML2 and the third light emitting layer EML3. The first passivation layer PTL1 may overlap the first light emitting element ED1 and may be spaced apart from (separated from) the second light emitting element ED2 and the third light emitting element ED3.

Next, in one or more embodiments, referring to FIG. 9, the first passivation layer PTL1 may be between (e.g., disposed between) the first electron transport layer ETL1 and the second electrode E2. The first passivation layer PTL1 may be in contact with the first electron transport layer ETL1 and the second electrode E2. The first passivation layer PTL1 may be the same as the first passivation layer PTL1 in the embodiment of FIG. 6, except for the location of the first passivation layer PTL1.

As used herein, the terms “substantially,” “about,” and similar terms are used as terms of approximation and not as terms of degree, and are intended to account for the inherent deviations in measured or calculated values that would be recognized by those of ordinary skill in the art. “About” or “approximately,” as used herein, is also inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

In the context of the present disclosure and unless otherwise defined, the terms “use,” “using,” and “used” may be considered synonymous with the terms “utilize,” “utilizing,” and “utilized,” respectively.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Although the embodiments of the present disclosure have been described in detail above, the scope of the present disclosure is not limited thereto, and various suitable modifications and improvements made by those skilled in the art using the basic concepts of the present disclosure defined in the following claims are also possible.

### Reference Numerals

RLA: red light emitting region
GLA: green light emitting region
BLA: blue light emitting region
SUB: substrate
ED1, ED2, ED3: light emitting element
PTL1: first passivation layer

What is claimed is:

1. A display device, comprising:
a substrate comprising a red light emitting region, a green light emitting region, and a blue light emitting region;
a transistor on the substrate;
a first light emitting element electrically connected to the transistor and overlapping the blue light emitting region; and
a capping layer on the first light emitting element,
wherein the first light emitting element comprises:
a first electrode;
a first light emitting layer on the first electrode;
a first electron transport layer on the first light emitting layer; and
a second electrode on the first electron transport layer,
wherein a first passivation layer is on one of between the second electrode and the capping layer, between the second electrode and the first electron transport layer, or on an upper surface of the capping layer, and
the first passivation layer is spaced apart from the red light emitting region and the green light emitting region.

2. The display device of claim 1, wherein:
the first passivation layer is between the second electrode and the capping layer.

3. The display device of claim 2, further comprising:
a blue color filter between the first passivation layer and the capping layer.

4. The display device of claim 1, wherein:
the first passivation layer is between the first electron transport layer and the second electrode.

5. The display device of claim 4, further comprising:
a blue color filter between the first passivation layer and the second electrode.

6. The display device of claim 1, further comprising:
a second light emitting element overlapping the red light emitting region, and
a third light emitting element overlapping the green light emitting region.

7. The display device of claim 6, wherein the second light emitting element comprises:
a second light emitting layer comprising a first quantum dot,
a second electron transport layer on the second light emitting layer, and
a second electrode on the second electron transport layer.

8. The display device of claim 7, wherein:
the second electron transport layer comprises ZnMgO.

9. The display device of claim 7, wherein the third light emitting element comprises:
a third light emitting layer comprising a second quantum dot,
a third electron transport layer on the third light emitting layer, and
a second electrode on the third electron transport layer.

10. The display device of claim 9, wherein:
the third electron transport layer comprises ZnMgO.

11. The display device of claim 1, wherein:
the first passivation layer comprises at least one of silicon nitride, silicon oxide, or silicon oxynitride.

12. The display device of claim 1, wherein:
the first light emitting layer comprises an organic material.

13. The display device of claim 9, wherein:
the second electron transport layer and the third electron transport layer comprise the same material.

14. The display device of claim 13, wherein:
the first electron transport layer comprises a material different from the second electron transport layer.

15. The display device of claim 13, wherein:
the first electron transport layer, the second electron transport layer, and the third electron transport layer are spaced apart from each other with a partition wall therebetween.

16. The display device of claim 13, wherein:
the first light emitting element comprises a first hole injection layer and a first hole transport layer,
the second light emitting element comprises a second hole injection layer and a second hole transport layer,
the third light emitting element comprises a third hole injection layer and a third hole transport layer,
the first hole injection layer, the second hole injection layer, and the third hole injection layer are spaced apart from each other, and
the first hole transport layer, the second hole transport layer, and the third hole transport layer are spaced apart from each other.

17. A display device, comprising:
a substrate comprising a red light emitting region, a green light emitting region, and a blue light emitting region;
a plurality of transistors on the substrate;
a first light emitting element, a second light emitting element, and a third light emitting element each electrically connected to the plurality of transistors and emitting light of different colors;
a capping layer on the first light emitting element, the second light emitting element, and the third light emitting element, and
a first passivation layer between the first light emitting element and the capping layer,
wherein the first light emitting element comprises:
a first electrode;
a first light emitting layer on the first electrode;
a first electron transport layer on the first light emitting layer, and
a second electrode on the first electron transport layer, and
wherein the second light emitting element comprises:
a second light emitting layer, the third light emitting element comprises a third light emitting layer, and
the first passivation layer is spaced apart from the second light emitting layer and the third light emitting layer along a thickness direction of the substrate.

18. The display device of claim 17, further comprising:
a partition wall between the first light emitting layer, the second light emitting layer, and the third light emitting layer, and
the second electrode and the capping layer are continuously provided across the first light emitting layer, the second light emitting layer, and the third light emitting layer.

19. The display device of claim 18, wherein:
the second light emitting element further comprises a second electron transport layer on the second light emitting layer,
the third light emitting element further comprises a third electron transport layer on the third light emitting layer,
the first electron transport layer, the second electron transport layer, and the third electron transport layer are spaced apart from each other with an upper partition wall therebetween,
the second electron transport layer and the third electron transport layer comprise the same material, and
the second electron transport layer and the first electron transport layer comprise different materials.

20. The display device of claim 17, further comprising:
a blue color filter in contact with the first passivation layer.

21. The display device of claim 20, wherein:
the blue color filter is on the second electrode,
the first passivation layer is on the blue color filter, and
the capping layer is on the first passivation layer.
